(19) United States
(12) Patent Application Publication
(10) Pub. No.: US 2025/0143058 A1
(43) Pub. Date: May 1, 2025

(54) METHOD FOR MANUFACTURING A DISPLAY PANEL, DISPLAY PANEL AND DISPLAY DEVICE

(71) Applicant: Hubei Yangtze Industrial Innovation Center Of Advanced Display Co., Ltd., Wuhan (CN)

(72) Inventors: Lei WANG, Wuhan (CN); Jun YAN, Wuhan (CN); You GAO, Wuhan (CN)

(21) Appl. No.: 18/957,919

(22) Filed: Nov. 25, 2024

(30) Foreign Application Priority Data
Aug. 16, 2024 (CN) 202411134875.0

(51) Int. Cl. H10H 29/855; H01L 25/075; H10H 29/01; H10H 29/80

(52) U.S. Cl. CPC H10H 29/8552; H01L 25/0753; H10H 29/0363; H10H 29/942

(57) ABSTRACT

Provided are a method for manufacturing a display panel, a display panel and a display device, which relate to the field of display technology and are used to optimize the performance of the display panel. The method includes: forming a light-emitting device layer on one side of a substrate, the light-emitting device layer including a plurality of light-emitting elements; forming a first light management layer on a side of the light-emitting device layer away from the substrate, the first light management layer including a plurality of openings spaced apart from each other; forming a second light management layer, at least part of which being located in the openings, the second light management layer including resin and dye, a photocuring treatment and a thermal curing treatment are performed during the formation of the second light management layer, and the photocuring treatment is performed earlier than the thermal curing treatment.

### CROSS-REFERENCE TO RELATED APPLICATIONS

The present disclosure claims priority to Chinese Application No. 202411134875.0 with the application title of “METHOD FOR MANUFACTURING A DISPLAY PANEL, DISPLAY PANEL AND DISPLAY DEVICE”, filed on Aug. 16, 2024, the content of which is incorporated herein by reference in its entirety.

### TECHNICAL FIELD

The present disclosure relates to the field of display technology, and more particularly to a method for manufacturing a display panel, a display panel and a display device.

### BACKGROUND

Organic light-emitting diode (OLED) display panels are widely used in various display products due to their excellent characteristics such as self-emitting, fast response, and high efficiency.

To reduce reflection, such display panels are usually equipped with filter structures for filtering ambient light. However, the performance of existing filter structures is not good, resulting in the need to further improve the anti-reflection capability of display panels.

### SUMMARY

The embodiments of the present disclosure provide a method for manufacturing a display panel, a display panel and a display device, aimed at optimizing the performance of the display panel.

In a first aspect, the embodiments of the present disclosure provide a method for manufacturing a display panel, including:
forming a light-emitting device layer on one side of a substrate, the light-emitting device layer including a plurality of light-emitting elements;
forming a first light management layer on a side of the light-emitting device layer away from the substrate, the first light management layer including a plurality of openings spaced apart from each other;
forming a second light management layer, at least part of which being located within the openings, and the second light management layer including resin and dye, a photocuring treatment and a thermal curing treatment being performed during the formation of the second light management layer, and the photocuring treatment is performed earlier than the thermal curing treatment.

In a second aspect, based on the same inventive concept, the embodiments of the present disclosure also provide a display panel, including:
a substrate;
a light-emitting device layer located on one side of the substrate, the light-emitting device layer including a plurality of light-emitting elements;
a first light management layer located on a side of the light-emitting device layer away from the substrate, the first light management layer including a plurality of openings spaced apart from each other;
a second light management layer, at least part of which being located within the openings, and the second light management layer including resin and dye.

In a third aspect, based on the same inventive concept, the embodiments of the present disclosure also provide a display device, including the above display panel.

The technical solution provided by the embodiment of the present disclosure has the following beneficial effects:
During the process of forming the second light management layer, a process of performing the photocuring treatment on the film layer to be processed is added before performing the thermal curing treatment on the film layer to be processed. The specific process of forming the second light management layer may be as follows: first, the resin composition material is placed on one side of the first light management layer to form the film layer to be processed. The resin composition material may include not only dye and base resin, but also a photoinitiator, thermal initiator and monomers. Then, the photocuring treatment is performed on the film layer to be processed. During this process, under the action of the photoinitiator, the double bonds of free monomers in the resin composition material will open, and then undergo addition reactions with unsaturated bonds of the base resin to achieve crosslinking and curing, connecting the monomers and resin molecules together. After the photocuring is completed, the thermal curing treatment is performed on the film layer to be processed. During this process, under the action of the thermal initiator, the double bonds of the monomers that were not opened during the photocuring treatment are opened, allowing the monomers to connect more tightly with the resin molecules, further increasing the degree of crosslinking and making the network structure more compact.

Through the two curing processes of photocuring and thermal curing, the curing degree of the second light management layer may be significantly improved, resulting in a significant increase in the density of the material of the second light management layer. As a result, the pores of the material of the second light management layer are denser, which may effectively intercept the movement of the dye, making it more difficult for the dye to diffuse and less likely to migrate to other film layers. The filtering performance of the second light management layer is more stable, and the anti-reflection performance of the display panel will also be better.

In addition, with the photocuring treatment, the curing rate of the overall second light management layer is improved, and in the second light management layer, whether the upper half away from the substrate or the lower half close to the substrate, has a high and uniform degree of curing, which may intercept the movement of the dye at various locations and prevent the dye from moving in various directions, resulting in better improvement of dye migration.

### BRIEF DESCRIPTION OF DRAWINGS

In order to more clearly illustrate the technical solutions in the embodiments of the present disclosure or the related art, the drawings required for the description of the embodiments or the related art will be briefly introduced below. It is apparent that the drawings described below are some embodiments of the present disclosure. For those skilled in the art, other drawings may be obtained based on these drawings without creative efforts.

FIG. 1 is a schematic structural diagram of a display panel according to an embodiment of the present disclosure;

FIG. 2 is a flowchart of a method for manufacturing a display panel according to an embodiment of the present disclosure;

FIG. 3 is a structural flowchart of a method for manufacturing a display panel according to an embodiment of the present disclosure;

FIG. 4 is another structural flowchart of a method for manufacturing a display panel according to the embodiment of the present disclosure;

FIG. 5 is a schematic diagram of a crosslinking reaction according to an embodiment of the present disclosure;

FIG. 6 is a schematic diagram of another crosslinking reaction according to an embodiment of the present disclosure;

FIG. 7 is another structural flowchart of a method for manufacturing a display panel according to an embodiment of the present disclosure;

FIG. 8 is another structural flowchart of a method for manufacturing a display panel according to the embodiment of the present disclosure;

FIG. 9 is another structural schematic diagram of a display panel according to an embodiment of the present disclosure;

FIG. 10 is another structural flowchart of a method for manufacturing a display panel according to an embodiment of the present disclosure;

FIG. 11 is a schematic structural diagram of a display device according to an embodiment of the present disclosure.

### DESCRIPTION OF EMBODIMENTS

To better understand the technical solutions of the present disclosure, the embodiments of the present disclosure will be described in detail below in conjunction with the drawings.

It should be clarified that the described embodiments are merely some embodiments of the present disclosure, and not all embodiments. Based on the embodiments of the present disclosure, all other embodiments obtained by those skilled in the art without creative efforts are within the protection scope of the present disclosure.

The term used in the embodiments of the present disclosure is for the purpose of describing particular embodiments only and is not intended to limit the present disclosure. The singular forms “a/an” “said” and “the” used in the embodiments and the appended claims are also intended to include the plural forms, unless the context clearly indicates otherwise.

It should be understood that the term “and/or” used herein is merely a description of the associative relationship between associated objects, indicating that three relationships may exist, for example, A and/or B, which may represent: A alone, A and B simultaneously, and B alone. In addition, the character “/” in this document generally indicates that the associated objects are in an “or” relationship.

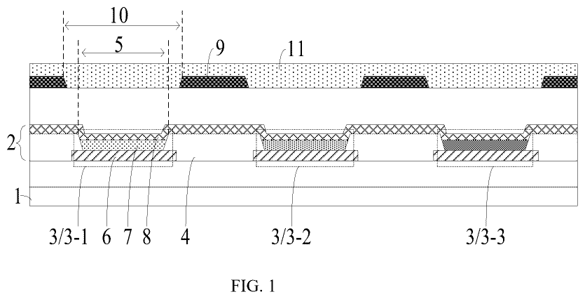

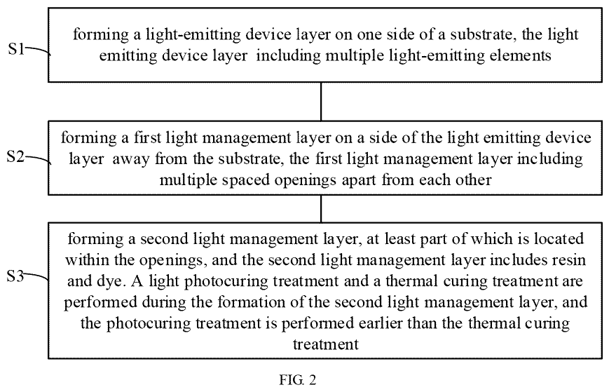

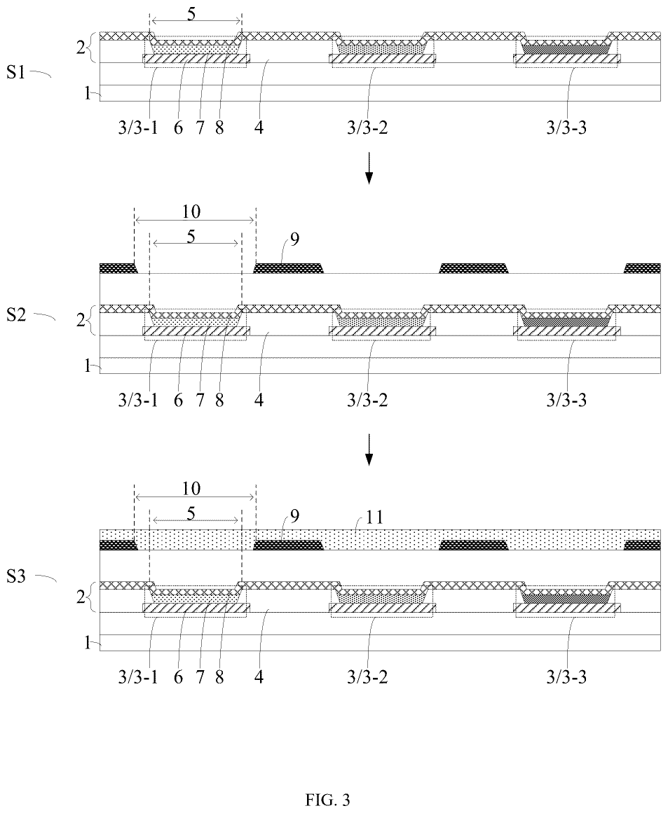

An embodiment of the present disclosure provides a method for manufacturing a display panel, as shown in FIGS. 1 to 3. FIG. 1 is a schematic structural diagram of a display panel provided by an embodiment of the present disclosure, FIG. 2 is a flowchart of a method for manufacturing a display panel provided by an embodiment of the present disclosure, and FIG. 3 is a structural flowchart of a method for manufacturing a display panel provided by the embodiment of the present disclosure. The method includes:

Step S1: forming a light-emitting device layer 2 on one side of a substrate 1, the light-emitting device layer 2 including multiple light-emitting elements 3.

More specifically, the light-emitting device layer 2 further includes a pixel defining layer 4, which includes multiple pixel openings 5. A light-emitting element 3 includes an anode 6, a light-emitting layer 7 and a cathode 8, the light-emitting layer 7 is located within a pixel opening 5.

Step S2: forming a first light management layer 9 on a side of the light-emitting device layer 2 away from the substrate 1, the first light management layer 9 including multiple openings 10 spaced apart from each other.

The first light management layer 9 may include a black light-shielding or light-absorbing material. In the direction perpendicular to the plane of the substrate 1, the multiple openings 10 overlap with the multiple light-emitting elements 3 respectively, and the size of the opening 10 may be larger than the size of its corresponding pixel opening 5. In other words, in the direction perpendicular to the plane of the substrate 1, the pixel opening 5 are located within its corresponding opening 10, and the edges of the opening 10 overlap with the pixel defining layer 4. This allows some large-angle light emitted by the light-emitting elements 3 to pass through the opening 10, increasing the light emission angle.

Step S3: forming a second light management layer 11, at least part of which is located within the openings 10, and the second light management layer 11 includes resin and dye. A light photocuring treatment and a thermal curing treatment are performed during the formation of the second light management layer 11, and the photocuring treatment is performed earlier than the thermal curing treatment.

The resin may include at least one of acrylic resin, epoxy resin, and polyurethane resin.

The dye is used to absorb light within a certain wavelength range, and the wavelength range of the light absorbed by the dye deviates from the emission wavelength range of the light-emitting elements 3. For example, if the multiple light-emitting elements 3 include a red light-emitting element 3-1, a green light-emitting element 3-2, and a blue light-emitting element 3-3, the wavelength range of the light absorbed by the dye deviates simultaneously from the wavelength range of the red light emitted by the red light-emitting element 3-1, the wavelength range of the green light emitted by the green light-emitting element 3-2, and the wavelength range of the blue light emitted by the blue light-emitting element 3-3. In one embodiment, the dye may absorb light within the wavelength range of 480 nm to 500 nm and/or absorb light within the wavelength range of 585 nm to 605 nm.

In the embodiment of the present disclosure, the second light management layer 11 may include dye, or dye and pigment. For example, the second light management layer 11 may include compounds based on tetraazaporphyrin (TAP), porphyrin, metalloporphyrin, oxazine, squarylium, triarylmethane, polymethine, tetrathiafulvalene, phthalocyanine, azo, perylene, xanthene, diarylmethane, dipyrromethene or cyanine, and combinations thereof.

In the formed panel structure, the first light management layer 9 and the second light management layer 11 constitute a light filtering structure. The first light management layer 9 functions as a black matrix to limit the light emission range of the light-emitting elements 3. The second light management layer 11 may replace the traditional color filter, as the wavelength range of the light absorbed by the dye in the second light management layer 11 deviates from the emission wavelength range of the light-emitting elements 3, the light emitted by the light-emitting elements 3 may normally pass through the openings 10 and emit through the second light management layer 11. At the same time, when external ambient light enters the display panel and reaches the second light management layer 11, some ambient light will be absorbed by the dye and may not be further transmitted inward, thereby effectively reducing the amount of ambient light entering the interior of the display panel and lowering panel reflection.

Currently, in the related process for functional film layers, first, a film layer to be processed is formed within the region where the functional film layer needs to be formed, and then the thermal curing treatment is performed on the film layer to be processed, making the film layer to be processed sturdy, thereby forming the final functional film layer.

However, the inventor found through research that if the second light management layer 11 is still formed using the conventional process, there will be some undesirable problems:

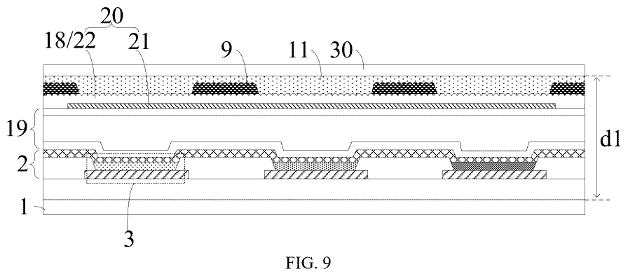

The second light management layer 11 includes dye, which may include various types such as migratory cationic dye, dispersive cationic dye and electronegative dye. However, dye molecules have small molecular weights, high migration rates, and low affinity with resin. Referring to FIG. 9, when an optical adhesive layer 30 is disposed above the second light management layer 11, if the electronegativity of the material of the optical adhesive layer 30 is high, the dye in the second light management layer 11 may easily diffuse into the optical adhesive layer 30 and combine with it, resulting in a decrease in the light filtering effect of the second light management layer 11, and in severe cases, even causing the second light management layer 11 to fail.

If the second light management layer 11 is still formed using the above-mentioned conventional process, during its formation, first, the resin composition material is disposed on one side of the first light management layer 9 to form a film layer to be processed, the resin composition material is the material used to form the second light management layer 11 and include base resin and dye. It is understandable that since the film layer to be processed needs to be subjected to the thermal curing treatment, the resin composition material may also include a thermal initiator. Then, the film layer to be processed is subjected to the thermal curing treatment to form the final second light management layer 11.

However, there will be a large amount of unreacted monomers inside the material of the second light management layer 11 formed in this way, and even if some monomers crosslink with the resin macromolecules during the thermal curing treatment, the degree of crosslinking is very small, resulting in poor compactness of the material of the second light management layer 11 and the material is loose and porous. The poor compactness of the material of the second light management layer 11 will allow the movement of the dye within the material to be almost unrestricted, which undoubtedly facilitates the movement of the dye, making the dye easier to migrate into the optical adhesive layer 30.

Therefore, the embodiment of the present disclosure proposes that a process of performing the photocuring treatment on the film layer to be processed is added before performing the thermal curing treatment on the film layer to be processed during the process of forming the second light management layer 11. The specific process of forming the second light management layer 11 may be as follows: first, the resin composition material is placed on one side of the first light management layer 9 to form the film layer to be processed. The resin composition material may include not only dye and base resin, but also a photoinitiator and thermal initiator. Then, the photocuring treatment is performed on the film layer to be processed. During this process, under the action of the photoinitiator, the double bonds of free monomers in the resin composition material will open, and then undergo addition reactions with unsaturated bonds of the base resin to achieve crosslinking and curing, connecting the monomers and resin molecules together. After the photocuring is completed, the thermal curing treatment is performed on the film layer to be processed. During this process, under the action of the thermal initiator, the double bonds of the monomers that were not opened during the photocuring treatment are opened, allowing the monomers to connect more tightly with the resin molecules, further increasing the degree of crosslinking and making the network structure more compact.

Through the two curing processes of photocuring and thermal curing, the curing degree of the second light management layer 11 may be significantly improved, resulting in a significant increase in the density of the material of the second light management layer 11. As a result, the pores of the material of the second light management layer 11 are denser, which may effectively intercept the movement of the dye, making it more difficult for the dye to diffuse and less likely to migrate to other film layers. The filtering performance of the second light management layer 11 is more stable, and the anti-reflection performance of the display panel will also be better.

In addition, the inventor also studied some other technical solutions that may improve the migration of the dye. For example, the second light management layer 11 may be cured through a plasma dry etching process, in which the plasma hardens the surface of the second light management layer 11 during the plasma dry etching process to form first and second parts having different curing rates. The first part is located on the side of the second part away from the first light management layer 9, that is, the first part is the upper half of the second light management layer 11, and the curing rate of the first part is greater than that of the second part.

However, this method can only use the first part with the high curing rate to intercept the upward migration of the dye, but may not effectively intercept the downward migration of the dye. In some panel structures, an optical adhesive layer may also be provided below the first light management layer 9, allowing the second light management layer 11 to contact the underlying optical adhesive layer through the openings 10. However, this structure may not effectively improve dye migration using the above solution.

However, in the technical solution provided by the embodiment of the present disclosure, with the photocuring treatment, the curing rate of the overall second light management layer 11 is improved, and in the second light management layer 11, whether the upper half away from the substrate 1 or the lower half close to the substrate 1, has a high and uniform degree of curing, which may intercept the movement of the dye at various locations and prevent the dye from moving in various directions, resulting in better improvement of dye migration.

In addition, it should be noted that in the embodiment of the present disclosure, the resin composition material used to form the second light management layer 11 may include some other additives in addition to the dye, the base resin, the photoinitiator, and the thermal initiator. The present disclosure does not specifically limit this.

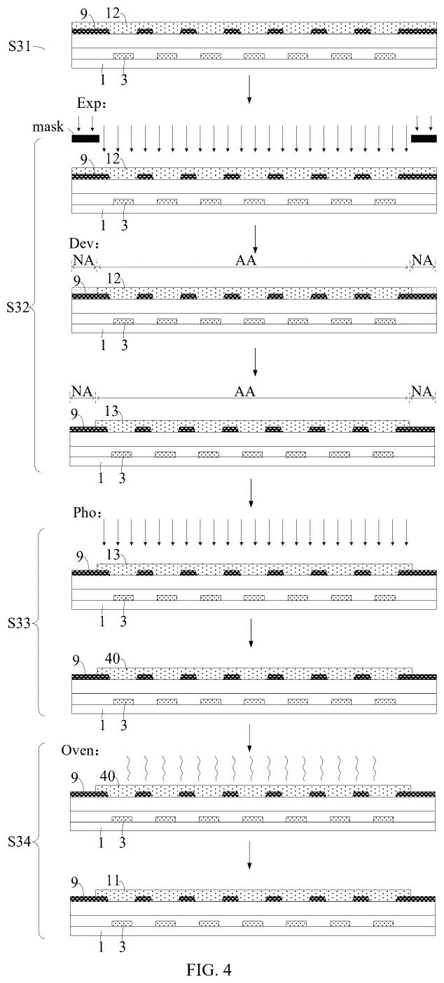

A feasible implementation is shown in FIG. 4. FIG. 4 depicts another structural flowchart of a method for manufacturing a display panel provided by an embodiment of the present disclosure. Specifically, Step S3 may include:

Step S31: coating a resin composition material on a side of the first light management layer 9 away from the substrate 1 to form a first film layer 12 to be processed, the resin composition material including monomers, base resin, the dye, and a photoinitiator.

The base resin may be resin prepolymer containing unsaturated double bonds or polymer matrix with a relatively small molecular weight, such as acrylic resin, epoxy resin, phenolic resin, polyamide resin, polyimide resin, etc. The present disclosure does not specifically limit the type of base resin. Additionally, the resin composition material may also include monomers including unsaturated double bonds, such as acrylic monomers, styrene monomers, epoxy monomers, etc., without limitation on the specific types.

Step S32: performing an exposure treatment (Exp) and a development treatment (Dev) on the first film layer 12 to be processed to form a second film layer 13 to be processed.

Specifically, referring to FIG. 4, during the exposure treatment (Exp), a mask is placed above the first film layer 12 to be processed, and ultraviolet light is used to irradiate the first film layer 12 to be processed. During the development treatment (Dev), the panel to be processed is placed in a developer, which removes part of the first film layer 12 to be processed to form the second film layer 13 to be processed.

Step S33: performing a photocuring treatment (Pho) on the second film layer 13 to be processed to form a third film layer 40 to be processed.

Step S34: performing a thermal curing treatment (Oven) on the third film layer 40 to be processed to form the second light management layer 11.

In the above process, the second film layer 13 to be processed is formed using the exposure and development methods, so that the second film layer 13 is only located in the area where the second light management layer 11 needs to be arranged. For example, referring to FIG. 4, when the second light management layer 11 only needs to cover the display area AA, in Step S32, the exposure and development treatments may be used to remove the first film layer 12 to be processed in the non-display area NA, making the second film layer 13 to be processed only in the display area AA. Alternatively, when the second light management layer 11 is designed as a non-full layer with a specific pattern, in Step S32, the second film layer 13 to be processed may also be exposed and developed to have a specific pattern.

During the exposure treatment, ultraviolet light is also used for irradiation. The aforementioned photocuring treatment is an additional step following the exposure treatment. During the photocuring treatment, the resin composition material may undergo a greater degree of crosslinking reaction compared to the exposure treatment by changing process conditions such as the wavelength of the ultraviolet light and the exposure time.

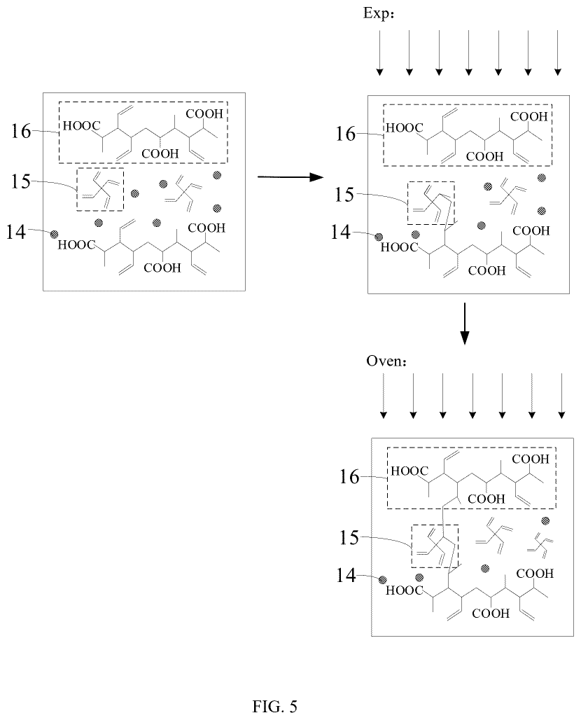

For example, the focus of the exposure treatment is to ensure that the film layer in the exposed area becomes easily soluble or insoluble, allowing the film layer in the exposed area or non-exposed area to be removed during the subsequent development treatment. Currently, the requirement for the degree of curing of the film layer during exposure treatment does not need to be too high. Referring to FIG. 5, which shows a schematic diagram of crosslinking reactions provided by an embodiment of the present disclosure. During the exposure treatment (Exp), the photoinitiator 14 in the resin composition material may not absorb a large amount of the ultraviolet light used for exposure, and the degree of crosslinking between the monomer 15 and the base resin 16 in the resin composition material is relatively small. Even after the subsequent thermal curing treatment, although the degree of crosslinking increases to some extent, a large amount of unreacted monomers still remain in the materials.

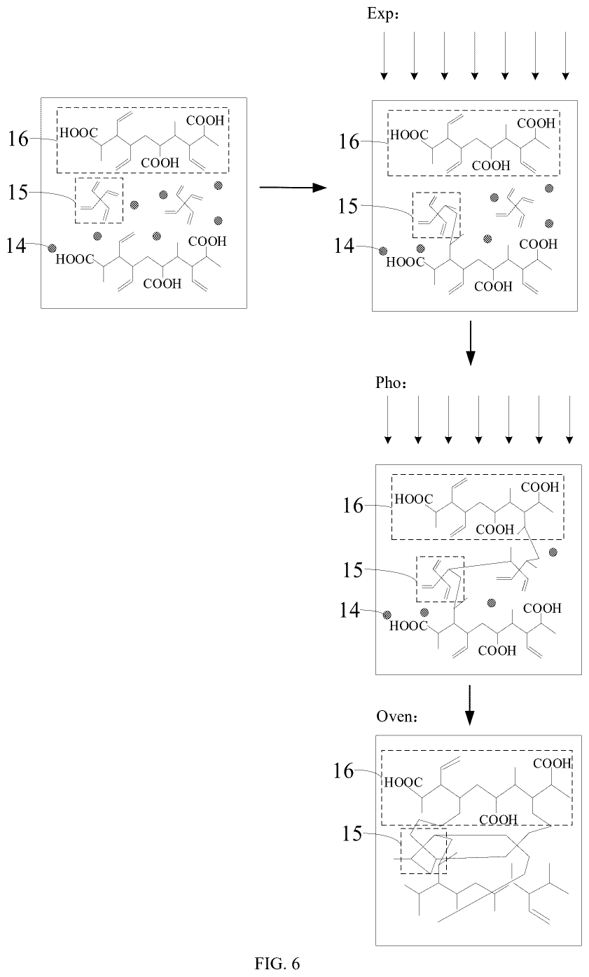

Referring to FIG. 6, which shows another schematic diagram of crosslinking reactions provided by an embodiment of the present disclosure. By adding the photocuring treatment (Pho) between the exposure treatment (Exp) and the thermal curing treatment (Oven), the curing rate of the film layer may be specifically improved during this process. For example, based on the photoinitiator 14 included in the material, a more absorptive ultraviolet light may be selected for irradiation, enabling the photoinitiator 14 to promote the crosslinking reaction between the monomer 15 and the base resin 16 to a greater extent, significantly increasing the curing degree of the film layer.

From another perspective, the above manufacturing method does not require changing process conditions and parameters of original exposure treatment and development treatment; only an additional photocuring treatment after the exposure and development treatments is needed. By adjusting the process conditions of the photocuring treatment, the curing degree of the second light management layer 11 may be further improved.

In a feasible implementation, ultraviolet light is used for irradiation during both the exposure treatment and the photocuring treatment, where the wavelength of the ultraviolet light used during the photocuring treatment is greater than that used during the exposure process.

The ultraviolet light with a longer wavelength may penetrate the material more deeply. Therefore, using ultraviolet light with a longer wavelength during the photocuring treatment may cause more photoinitiators to react under light irradiation, increasing the degree of crosslinking between the monomers and the resin macromolecules.

In a feasible implementation, i-line ultraviolet light is used for irradiation during the photocuring treatment, where the i-line ultraviolet light refers to the ultraviolet light with a wavelength of approximately 365 nm.

Currently, more photoinitiators are used to have better absorption of the i-line ultraviolet light. Therefore, using the i-line ultraviolet light for irradiation during the photocuring treatment is more conducive to increasing the degree of crosslinking. In an embodiment of the present disclosure, the photoinitiators in the resin composition material may include isopropylthioxanthone, 9,10-phenanthrenequinone, benzophenone, phenylbis(2,4,6-trimethylbenzoyl) phosphine oxide (also known as 819 photoinitiator), etc. These photoinitiators have good absorption capabilities for ultraviolet light around 365 nm.

Furthermore, the exposure energy during the photocuring treatment is less than 600 mj. This may prevent some adverse problems caused by excessive exposure energy during the photocuring treatment. For example, it may avoid overcuring, prevent the second light management layer 11 from becoming too hard and prone to cracks, and avoid excessive heat generated during the photocuring treatment from damaging the underlying film layers or devices.

In a feasible implementation, the curing rate of the second light management layer 11 is greater than or equal to 90%.

When the second light management layer 11 is formed using the above conventional processes, the curing rate of the formed second light management layer 11 may typically only reach 60% to 80%. However, by adding the photocuring treatment during the formation of the second light management layer 11, the curing rate of the finally formed second light management layer 11 may reach 90% or higher, resulting in a higher density and lower porosity of the material of the second light management layer 11, significantly improving the dye migration.

The curing rate of the second light management layer 11 may be measured using a Fourier transform infrared spectrometer.

In a feasible implementation, the base resin includes negative photosensitive resin.

When the resin composition includes the negative photosensitive resin, the resin composition material may be considered as a negative photoresist. According to the characteristics of the material of the negative photoresist, referring to FIG. 4, during exposure and development treatments, the film layer in the non-exposed area dissolves in the developer and is removed, while the film layer in the exposed area is retained. This means that the retained film layer undergoes both the exposure treatment and the subsequent photocuring treatment, resulting in a greater degree of crosslinking and the materials are denser.

In a feasible implementation, after forming the first film layer 12 to be processed by coating and before performing the exposure treatment on the first film layer 12 to be processed, the first film layer 12 to be processed may be subjected to a vacuum drying (VCD) treatment.

When coating the resin composition material to form the first film layer 12 to be processed, the resin composition material usually contains solvents, such as some organic solvents. The solvents may serve as diluents, reducing the viscosity of the material, improving fluidity, and enabling them to distribute more evenly to form a smoother film layer.

In an embodiment of the present disclosure, the solvents used may include propylene carbonate, butoxyethanol, butoxyethyl acetate, toluene, xylene, butyl carbitol acetate, cyclohexanone, propylene glycol monomethyl ether, dipropylene glycol diethyl ether, and methyl carbitol acetate, etc. Before exposing the first film layer 12 to be processed, performing the vacuum drying process on the first film layer 12 to be processed may volatilize the solvents in the resin composition material, and maintain the stability of the composition and properties of the resin composition material. In one method of vacuum drying, the air in the box may be pumped out by a vacuum pump to form the vacuum environment, which lowers the boiling point of the solvents, enabling the solvents in the resin composition material to evaporate quickly at a lower temperature, achieving the purpose of drying.

In a feasible embodiment, after performing the vacuum drying treatment on the first film layer 12 to be processed, a soft bake (SBK) treatment may also be performed on the first film layer 12 to be processed, so as to further remove the solvents in the resin composition material, and increase the viscosity and adhesion of the resin composition material, preventing the resin composition material from generating bubbles or water marks during the subsequent exposure treatment.

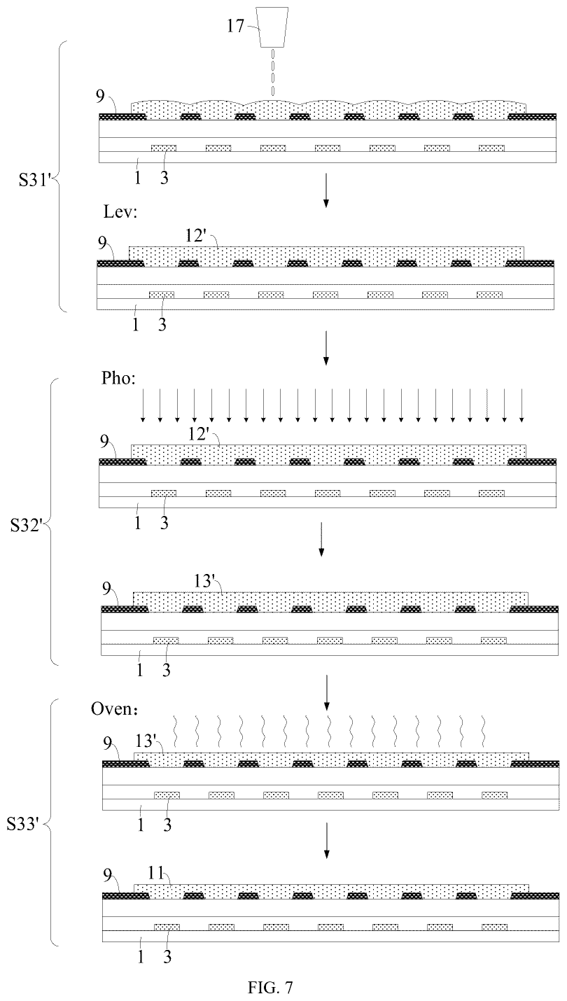

In a feasible embodiment, as shown in FIG. 7, which is another structural flowchart of a method for manufacturing a display panel provided by an embodiment of the present disclosure, step S3 may specifically include:

Step S31′: Using inkjet printing, the resin composition material containing the resin, the dye, and the photoinitiator are sprayed onto the side of the first light management layer 9 away from the substrate 1 by a nozzle 17 to form a first film layer 12′ to be processed.

Step S32′: the photocuring treatment (Pho) is performed on the first film layer 12′ to be processed to form a second film layer 13′.

Step S33′: the thermal curing treatment (Oven) is performed on the second film layer 13′ to be processed to form the second light management layer 11.

In the above process, the second light management layer 11 is formed using the inkjet printing process, which does not require etching and development. Since water or solvent is an auxiliary agent for dye migration, if the development treatment is omitted, the panel to be processed does not need to be placed in the developer. There is no migration aid in the process to help the dye migrate, thus effectively preventing dye migration during the formation of the first film layer 12′ to be processed. Coupled with the subsequent photocuring treatment and thermal curing treatment, the overall process has a more significant improvement effect on dye migration. In addition, the overall process of inkjet printing is also simpler.

In one feasible embodiment, the resin composition material is solvent-free.

As mentioned earlier, when exposing to form the second light management layer 11, it is necessary to first coating the resin composition material on the entire layer, and then remove the resin composition material in the partial area through exposure and development. In order to make the coating film more smooth, the process of coating the entire layer requires high fluidity of the material. Therefore, when preparing the resin composition material, solvents are usually added to reduce the viscosity of the material.

The inkjet printing process is different from the above process. In the process of forming the second light management layer 11 by inkjet printing, the first film layer 12′ to be processed in a specific area is directly formed by only spraying the resin composition material on the printing area, without coating the resin composition material first on the entire layer. Therefore, when forming the second light management layer 11 with the inkjet printing process, the accuracy is high and the requirement for the fluidity of the material may be reduced. In this regard, in the embodiment of the present disclosure, the resin composition material used for inkjet printing may also be made solvent-free, that is, when mixing the base resin, the monomer, the dye, and the photoinitiator to form the resin composition material, no solvent is added, thus greatly reducing the solvent in the second light management layer 11 formed, which may prevent the migration of dye into other film layers to a greater extent.

Furthermore, when the resin composition material is solvent-free, the viscosity of the resin composition material is greater than or equal to 20 cps, and may further be less than or equal to 25 cps.

As mentioned earlier, the resin composition material in the coating process has solvents, so the viscosity of the resin composition material involved in this method is relatively low, usually less than 5 cps, such as 2 cps to 3 cps. When the resin composition material in the inkjet printing process is solvent-free, the viscosity of the resin composition material involved in this method will be slightly higher than that of the resin composition material involved in the lithography process.

However, it should be noted that since the inkjet printing process uses a nozzle to directly spray the resin composition material within the printing area, the requirement for the fluidity of the material is relatively low. Therefore, even if the viscosity of the resin composition material is high, it will not affect the flatness of the film layer.

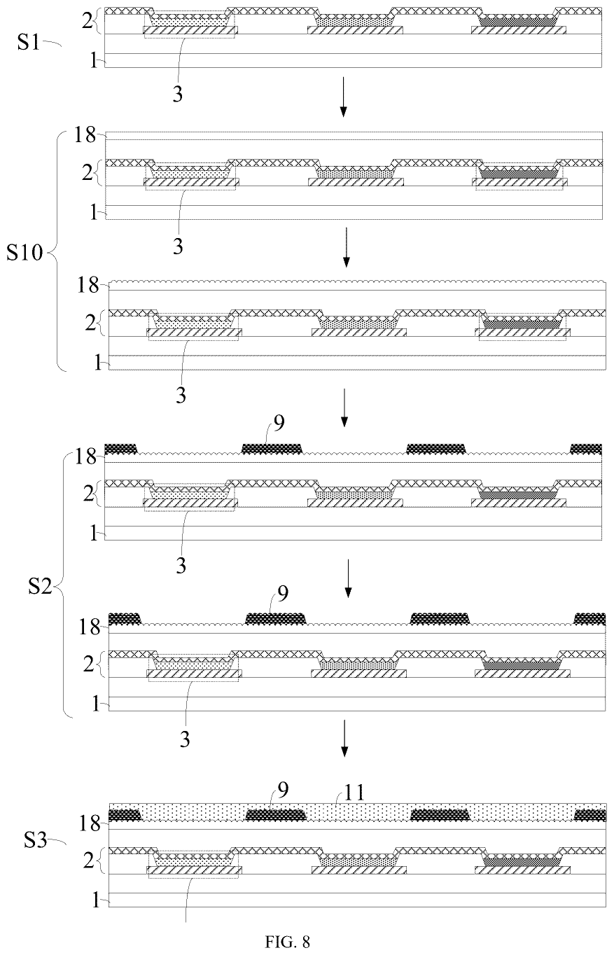

In a feasible embodiment, as shown in FIG. 8, which is another structural flowchart of the manufacturing method for a display panel provided by an embodiment of the present disclosure, before forming the first light management layer 9, the method further includes step S10: forming a first insulating layer 18, the first light management layer 9 is in contact with the first insulating layer 18, that is, in step S2, the first light management layer 9 is directly formed above the first insulating layer 18.

The first insulating layer 18 is a film layer in contact with and below the first light management layer 9. In one structure, as shown in FIG. 9, which is another structural diagram of the display panel provided by an embodiment of the disclosure, the display panel includes an encapsulation layer 19 and a touch layer 20 located on a side of the encapsulation layer 19 away from the substrate 1. The touch layer 20 includes at least one electrode layer 21 and a protective layer 22 located on a side of the electrode layer 21 away from the substrate 1. The first insulating layer 18 may be the protective layer 22.

Certainly, which film layer the first insulating layer 18 is specifically related to the film layer structure design of the display panel. For example, when the encapsulation layer is in contact with the first light management layer 9, the first insulating layer 18 may also be an inorganic encapsulation layer in the encapsulation layer. The embodiment of the present disclosure does not specifically limit it.

The surface energy difference between the first light management layer 9 and the resin composition material is greater than the threshold difference. Before spraying the resin composition material, the method further includes performing a rough treatment on the upper surface of the first light management layer 9 on a side away from the substrate 1. And/or, the surface energy difference between the first insulating layer 18 and the resin composition material is greater than the threshold difference. Before spraying the resin composition material, the method further includes performing a rough treatment on the upper surface of the first insulating layer 18 on a side away from the substrate 1.

In the embodiment of the present disclosure, the upper surfaces of the first insulating layer 18 and the first light management layer 9 may be roughened separately. For example, referring to FIG. 8 again, step S10 also includes performing a rough treatment on the first insulating layer 18 after forming the first insulating layer 18, and step S2 also includes performing a rough treatment on the first light management layer 9 after forming the first light management layer 9.

Alternatively, after the first light management layer 9 is formed, the upper surfaces of the first insulating layer 18 and the first light management layer 9 may be roughened simultaneously. In this case, only the portion of the first insulating layer 18 exposed by the openings 10 of the first light management layer 9 will exhibit a rough surface.

In the embodiment of the disclosure, the rough treatment may be specifically achieved by plasma treatment, laser etching, and other methods. The value of the threshold difference may be between 10 dyne/cm and 15 dyne/cm, for example, the threshold difference is 10 dyne/cm.

The resin composition material need to be sprayed over the first light management layer 9 and the first insulating layer 18. When the surface energy of the first light management layer 9 and/or the first insulating layer 18 is too different from that of the resin composition material, the resin composition material is not easily film-formed. By roughening the upper surface of the first light management layer 9 and/or the first insulating layer 18, on the one hand, the rough surface may provide more anchoring points, making it easier for the sprayed resin composition material to spread and adhere evenly, and making it easier for the resin composition material to form a film, on the other hand, the rough surface has a microscopic concave-convex structure, which may increase the contact area between the resin composition material and the underlying film layer, helping to improve the mechanical bonding force between the second light management layer 11 and the underlying film layer, enhancing the bonding strength, and making the film layer more stable. Finally, the rough surface may also disperse the stress that may occur between the contacting film layers, reducing the risk of film peeling caused by stress concentration.

In one feasible embodiment, the wavelength of the ultraviolet light used in the photocuring treatment is within the range of 190 nm-450 nm.

When forming the second light management layer 11 with the inkjet printing process, the process itself may utilize the characteristics such as no development and no solvent to reduce dye migration problems, thus allowing for a broader selection of ultraviolet light wavelengths during the photocuring treatment, thereby relaxing the restriction on the process conditions of the photocuring treatment. Of course, when forming the second light management layer 11 with the inkjet printing process, i-line ultraviolet light may also be used during the photocuring treatment to achieve a higher curing rate for the second light management layer 11.

In addition, referring to FIG. 7, in step S31′, after spraying the resin composition material, the resin composition material may also be subjected to a leveling treatment (Lev) to make the first film layer 12′ to be processed have a smoother surface.

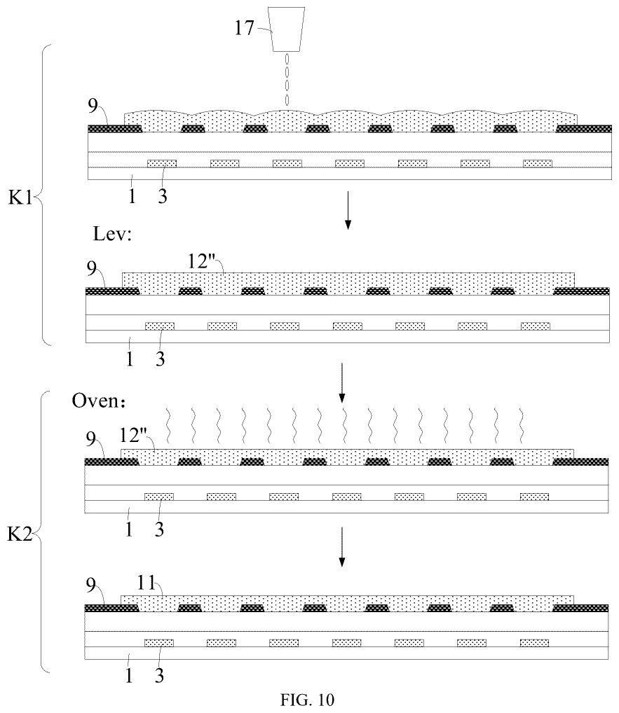

In a feasible embodiment, as shown in FIG. 10, which is a structural flowchart of another method for manufacturing a display panel provided by an embodiment of the present disclosure, the process of forming the second light management layer 11 may further include:

Step K1: Using the inkjet printing, resin composition material containing monomers, base resin, the dye, and the photoinitiator are sprayed onto a side of the first light management layer 9 away from the substrate 1 by a nozzle 17 to form a first film layer 12″ to be processed.

Furthermore, in step K1, after spraying the resin composition material, the resin composition material may also be subjected to the leveling treatment (Lev) to make the first film layer 12″ to be processed have a smoother surface.

Step K2: the thermal curing treatment is performed on the first film layer 12″ to be processed to form a second light management layer 11.

In this process, the second light management layer 11 is formed using the inkjet printing process, which may eliminate the development treatment. The panel to be processed does not need to be placed in the developer, and there is no migration aid such as the developer to help the dye migrate during the process, thus effectively preventing dye migration during the formation of the first film layer 12″ to be processed. Coupled with the subsequent thermal curing treatment, the overall process has a more significant improvement effect on dye migration. Although the process does not include the photocuring treatment, it may still achieve a certain degree of curing rate.

Furthermore, the resin composition material is solvent-free. In the process, there is not only no developer as a migration aid, but also no solvent as a migration aid, which may prevent the dye from migrating to other film layers to a greater extent.

In one feasible embodiment, referring again to FIG. 9, the distance between the surface of the second light management layer 11 away from the substrate 1 and the substrate 1 is a first distance d1, and the difference between the first distances d1 at different positions is less than or equal to 80 nm. Furthermore, the difference between the first distances d1 at different positions is less than or equal to 40 nm.

The upper surface of the second light management layer 11 formed in this way is more flat, which not only improves the flatness of the film layer, but also makes the distribution of the dye in the second light management layer 11 more uniform, thereby improving the reflection uniformity of the display panel.

For example, when the second light management layer 11 is formed using the exposure treatment, the resin composition material has solvents, so the solvents may be used to make the resin composition material uniformly coated, so that the upper surface of the second light management layer 11 finally formed is a flat surface. When the second light management layer 11 is formed using the inkjet printing process, after spraying the resin composition material, by using the leveling treatment, the upper surface of the second light management layer 11 finally formed is a flat surface.

In one feasible embodiment, the i-line ultraviolet light is used for irradiation during the photocuring treatment, and/or the curing rate of the second light management layer 11 is greater than or equal to 90%.

For example, when the second light management layer 11 is formed using the exposure treatment, in step S33, the photocuring treatment is performed on the second film layer 13 to be processed by using the i-line ultraviolet light. Alternatively, when the second light management layer 11 is formed using the inkjet printing process, in step S32′, the photocuring treatment is performed on the first film layer 12 to be processed by using the i-line ultraviolet light.

And/or, when forming the second light management layer 11 using the photolithography process, a combination of the exposure treatment, the photocuring treatment and the thermal curing treatment may achieve a curing rate of 90% or higher for the second light management layer 11. Alternatively, when the second light management layer 11 is formed using the inkjet printing process, a combination of no development, no solvent, the photocuring treatment and thermal curing treatment may achieve a curing rate of 90% for the second light management layer 11.

with the above method, the second light management layer 11 has a higher curing rate, and the pores of the second light management layer 11 are denser, which may intercept the movement of the dye to a greater extent.

Based on the same inventive concept, the embodiments of the present disclosure also provide a display panel, which is manufactured by the above method.

Referring to FIGS. 1-3, the display panel includes a substrate 1, a light-emitting device layer 2, a first light management layer 9, and a second light management layer 11. The light-emitting device layer 2 is located on one side of the substrate 1, and the light-emitting device layer 2 includes a plurality of light-emitting elements 3. The first light management layer 9 is located on a side of the light-emitting device layer 2 away from the substrate 1, and includes a plurality of openings 10 spaced apart from each other. At least part of the second light management layer 11 is located within the openings 10, the second light management layer 11 includes resin and dye. The above structures have been described in detail in the foregoing embodiments, and are not repeated here.

Based on the aforementioned analysis, it may be seen that due to the addition of photocuring treatment during the formation of the second light management layer 11 in the display panel, the second light management layer 11 has a higher degree of curing, and the pores of the material of the second light management layer 11 are denser, which may intercept the movement of the dye, making it more difficult for the dye to diffuse and not easily migrate to other film layers. The optical filtering performance of the second light management layer 11 is more stable, and the anti-reflection performance of the display panel is also better.

In one possible implementation, the second light management layer 11 is formed by an inkjet printing process.

In one embodiment, referring to FIG. 7, the formation process may include: firstly, a nozzle 17 is used to spray a resin composition material containing monomers, base resin, the dye, and a photoinitiator on a side of the first light management layer 9 away from the substrate 1 to form a first film layer 12′ to be processed. Then, a photocuring treatment (Pho) is performed on the first film layer 12′ to be processed to form a second film layer 13′ to be processed. Finally, a thermal curing treatment (Oven) is performed on the second film layer 13′ to be processed to form the second light management layer 11.

The second light management layer 11 formed in this process undergoes two curing processes, namely the photocuring treatment and the thermal curing treatment.

This type of second light management layer 11 does not require development during its formation process, so there is no need for a migration aid such as a developer to help the dye migrate, effectively reducing the risk of dye migration. In addition to the subsequent photocuring and thermal curing treatments, the material of the second light management layer 11 will be very dense, making it more difficult for the dye to migrate to other film layers.

In another embodiment, referring to FIG. 10, the formation process may also include: firstly, a nozzle 17 is used to spray a resin composition material containing monomers, base resin, the dye, and a photoinitiator on a side of the first light management layer 9 away from the substrate 1 to form a first film layer 12″ to be processed, and then a thermal curing treatment (Oven) is performed on the first film layer 12″ to be processed to form a second light management layer 11.

The second light management layer 11 formed in this process does not undergo the photocuring, but only undergo the thermal curing.

This type of light management layer 11 may already significantly improve the problem of dye migration based on the characteristic of no development. Although this process does not undergo photocuring, it may also achieve a certain curing rate.

Furthermore, the resin composition material sprayed during the formation process is solvent-free, meaning that when mixing the base resin, the monomer, the dye, and the photoinitiator to form the resin composition material, no solvent is added, which may further prevent dye migration into other film layers.

Furthermore, in both the inkjet printing and coating processes, by combining the photocuring treatment and thermal curing treatment, the curing rate of the second light management layer 11 may reach greater than or equal to 90%. At this point, the curing degree of the second light management layer 11 is higher, the film material is more compact, and the movement of the dye may be intercepted to a greater extent.

Further, the second light management layer 11 is formed through the photocuring treatment and thermal curing treatment, with the photocuring treatment being performed earlier than the thermal curing treatment. Based on the aforementioned analysis, the second light management layer 11 may be formed using the coating process or the inkjet printing process.

The use of the photocuring treatment may improve the curing rate of the entire second light management layer 11. In the second light management layer 11, whether the upper half away from the substrate 1 or the lower half close to the substrate 1, has a high and uniform degree of curing, which may intercept the movement of the dye at various locations and prevent the dye from moving in various directions, resulting in better improvement of dye migration.

In one feasible embodiment, referring to FIGS. 8 and 9, the surface energy difference between the first light management layer 9 and the second light management layer 11 is greater than the threshold difference, and the upper surface of the first light management layer 9 on a side away from the substrate 1 is a rough surface.

In another embodiment the display panel further may include a first insulating layer 18 located between the light-emitting device layer 2 and the first light management layer 9 and in contact with the first light management layer 9. The surface energy difference between the first insulating layer 18 and the second light management layer 11 is greater than the threshold difference, and the upper surface of the first insulating layer 18 on a side away from the substrate 1 is a rough surface.

As mentioned above, the first insulating layer 18 is a film layer that is in contact with the first light management layer 9 and below the first light management layer 9, which specifically may be the protective layer 22 in the touch layer 20.

When the second light management layer 11 is formed with the inkjet printing process, the resin composition material needs to be sprayed over the first light management layer 9 and the first insulating layer 18. When the surface energy of the first light management layer 9 and/or the first insulating layer 18 differs greatly from that of the resin composition material, the resin composition material is not easily film-formed. By roughening the upper surface of the first light management layer 9 and/or the first insulating layer 18, on the one hand, the rough surface may provide more anchoring points, making it easier for the sprayed resin composition material to spread and adhere evenly, and making it easier for the resin composition material to form a film. Also, the rough surface has a microscopic concave-convex structure, which may increase the contact area between the resin composition material and the underlying film layer, helping to improve the mechanical bonding force between the second light management layer 11 and the underlying film layer, enhancing the bonding strength, and making the film layer more stable. Finally, the rough surface may also disperse the stress that may occur between the contacting film layers, reducing the risk of film peeling caused by stress concentration.

In a feasible embodiment, referring to FIG. 9, the distance between the surface of the second light management layer 11 away from the substrate 1 and the substrate 1 is a first distance d1, and the difference between the first distances d1 at different positions is less than or equal to 80 nm. Furthermore, the difference between the first distances d1 at different positions is less than or equal to 40 nm.

At this time, the upper surface of the second light management layer 11 is more flat, which not only improves the flatness of the film layer, but also makes the distribution of the dye in the second light management layer 11 more uniform, thereby improving the reflection uniformity of the display panel.

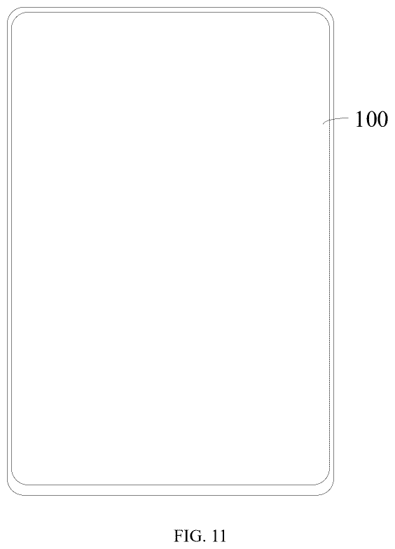

Based on the same inventive concept, the embodiment of the present disclosure also provides a display device, as shown in FIG. 11, which is a structural diagram of a display device provided by an embodiment of the present disclosure. The display device includes the above-mentioned display panel 100. Certainly, the display device shown in FIG. 11 is only a schematic illustration, and the display device may be any electronic device with display function, such as a mobile phone, tablet computer, laptop, e-book reader, or television.

The above description is only a preferred embodiment of the present disclosure and is not intended to limit the present disclosure. Any modifications, equivalent substitutions, improvements, etc. within the spirit and principles of the present disclosure should be included within the protection scope of the present disclosure.

Finally, it should be noted that the above embodiments are only used to illustrate the technical solutions of the present disclosure, not to limit them; Although the present disclosure has been described in detail with reference to the foregoing embodiments, those skilled in the art should understand that they may still modify the technical solutions described in the foregoing embodiments, or equivalently replace some or all of the technical features therein; These modifications or substitutions do not make the essence of the corresponding technical solutions deviate from the scope of the technical solutions of the embodiments of the present disclosure.

What is claimed is:

1. A method for manufacturing a display panel, comprising:
forming a light-emitting device layer on a side of a substrate, the light-emitting device layer comprising light-emitting elements;
forming a first light management layer on a side of the light-emitting device layer away from the substrate, the first light management layer comprising openings spaced apart from each other; and
forming a second light management layer, wherein at least part of the second light management layer is located in the openings, and the second light management layer comprises a resin and a dye, wherein a photocuring treatment and a thermal curing treatment are performed during the formatting of the second light management layer, and the photocuring treatment is performed earlier than the thermal curing treatment.

2. The method according to claim 1, wherein the forming the second light management layer comprises:
coating a resin composition material on a side of the first light management layer away from the substrate to form a first film layer to be processed, wherein the resin composition material comprises monomers, a base resin, the dye, and a photoinitiator;
performing an exposure treatment and a development treatment on the first film layer to be processed, to form a second film layer to be processed;
performing the photocuring treatment on the second film layer to be processed, to form a third film layer to be processed; and
performing the thermal curing treatment on the third film layer to be processed, to form the second light management layer.

3. The method according to claim 2, wherein
the exposure treatment and the photocuring treatment are performed with ultraviolet light for irradiation, and a wavelength of the ultraviolet light used during the photocuring treatment is greater than that used during the exposure process.

4. The method according to claim 2, wherein
the photocuring treatment is performed with i-line ultraviolet light for irradiation.

5. The method according to claim 4, wherein
during the photocuring treatment, exposure energy is less than 600 mj.

6. The method according to claim 2, wherein
a curing rate of the second light management layer is greater than or equal to 90%.

7. The method according to claim 2, wherein
the base resin comprises a negative photosensitive resin.

8. The method according to claim 1, wherein
the forming the second light management layer comprises:
spraying a resin composition material on a side of the first light management layer away from the substrate by inkjet printing to form a first film layer to be processed, wherein the resin composition material comprises monomers, a base resin, the dye, and a photoinitiator;
performing the photocuring treatment on the first film layer to be processed, to form a second film layer to be processed; and
performing the thermal curing treatment on the second film layer to be processed, to form the second light management layer.

9. The method according to claim 8, wherein
the resin composition material is solvent-free.

10. The method according to claim 9, wherein
the resin composition material has a viscosity greater than or equal to 20 cps.

11. The method according to claim 8, wherein before forming the first light management layer, the method further comprises:
forming a first insulating layer; wherein the first light management layer is in contact with the first insulating layer;
wherein a surface energy difference between the first light management layer and the resin composition material is greater than a threshold difference, and, the method further comprises: performing a rough treatment on an upper surface of the first light management layer on a side away from the substrate before spraying the resin composition material; and/or
wherein a surface energy difference between the first insulating layer and the resin composition material is greater than the threshold difference, and, the method further comprises: performing a rough treatment on an upper surface of the first insulating layer on a side away from the substrate before spraying the resin composition material.

12. The method according to claim 8, wherein a wavelength of the ultraviolet light during the photocuring treatment is within a range from 190 nm to 450 nm.

13. The method according to claim 1, wherein
a distance between a surface of the second light management layer away from the substrate and the substrate is a first distance, and a difference among the first distances at different positions is less than or equal to 80 nm.

14. The method according to claim 1, wherein
the photocuring treatment is performed with i-line ultraviolet light for irradiation, and/or
the second light management layer has a curing rate greater than or equal to 90%.

15. A display panel, comprising:
a substrate;
a light-emitting device layer located on a side of the substrate, the light-emitting device layer comprising light-emitting elements;
a first light management layer located on a side of the light-emitting device layer away from the substrate, the first light management layer comprising openings spaced apart from each other; and
a second light management layer, wherein at least part of second light management layer is located within the openings, and the second light management layer comprising a resin and a dye.

16. The display panel according to claim 15, wherein
the second light management layer is formed by an inkjet printing process, and/or
the second light management layer has a curing rate greater than or equal to 90%.

17. The display panel according to claim 16, wherein
the second light management layer is formed through a photocuring treatment and a thermal curing treatment, and the photocuring treatment is performed earlier than the thermal curing treatment.

18. The display panel according to claim 15, wherein
a surface energy difference between the first light management layer and the second light management layer is greater than a threshold difference, and an upper surface of the first light management layer on a side away from the substrate is a rough surface; and/or
the display panel further comprises a first insulating layer, and the first insulating layer is located between the light-emitting device layer and the first light management layer and is in contact with the first light management layer,
a surface energy difference between the first insulating layer and the second light management layer is greater than the threshold difference, and an upper surface of the first insulating layer on a side away from the substrate is a rough surface.

19. The display panel according to claim 15, wherein
a distance between a surface of the second light management layer away from the substrate and the substrate is a first distance, and a difference among the first distances at different positions is less than or equal to 80 nm.

20. A display device, comprising a display panel, wherein the display panel comprises:
a substrate;
a light-emitting device layer located on a side of the substrate, the light-emitting device layer comprising light-emitting elements;
a first light management layer located on a side of the light-emitting device layer away from the substrate, the first light management layer comprising openings spaced apart from each other, and
a second light management layer, wherein at least part of second light management layer is located within the openings, the second light management layer comprising a resin and a dye.
